(19) United States
(12) Patent Application Publication
(10) Pub. No.: US 2026/0178799 A1
(43) Pub. Date: Jun. 25, 2026

(54) METHOD FOR RAPIDLY CALCULATING CARBON CONCENTRATION DISTRIBUTION IN PULSE CARBURIZING PROCESS

(71) Applicant: BEIJING RESEARCH INSTITUTE OF MECHANICAL & ELECTRICAL TECHNOLOGY CO., LTD. CAM, Beijing (CN)

(72) Inventors: Jingbo MA, Beijing (CN); Peiwu CONG, Beijing (CN); Chao JIANG, Beijing (CN); Wenlin LU, Beijing (CN); Chunhui DU, Beijing (CN); Jiawei YAO, Beijing (CN); Guangwen YANG, Beijing (CN); Xuyang CHEN, Beijing (CN); Junxiang LIU, Beijing (CN); Longxiang HE, Beijing (CN); Danruo XUE, Beijing (CN)

(73) Assignee: BEIJING RESEARCH INSTITUTE OF MECHANICAL & ELECTRICAL TECHNOLOGY CO., LTD. CAM, Beijing (CN)

(21) Appl. No.: 18/840,342

(22) PCT Filed: Dec. 21, 2023
(86) PCT No.: PCT/CN2023/140454

§ 371 Date: Aug. 21, 2024

(30) Foreign Application Priority Data
May 25, 2023 (CN) 202310608184.9

(51) Int. Cl. G06F 30/28

(52) U.S. Cl. CPC G06F 30/28

(57) ABSTRACT

A method for rapidly calculating a carbon concentration distribution in a pulse carburizing process is provided. The method does not involve an iterative calculation process, can rapidly obtain a carbon concentration distribution at a certain time in the pulse carburizing process, distinguish between a boost process and a diffusion process based on a boundary condition, describe a vacuum low-pressure carburizing process, and present variations of a surface carbon concentration and a carburized depth in the vacuum low-pressure carburizing process over time. The method provided in the present application has high calculation efficiency, can be embedded in a computer such as an industrial personal computer with ordinary performance for use, may realize real-time display of a carbon concentration in a vacuum carburizing process, and can be used for industrial visual software.

### CROSS REFERENCE TO RELATED APPLICATION

This patent application is a national stage application of International Patent Application No. PCT/CN2023/140454, filed on Dec. 21, 2023, which claims the benefit and priority of Chinese Patent Application No. CN202310608184.9 filed with the China National Intellectual Property Administration on May 25, 2023, and entitled “METHOD FOR RAPIDLY CALCULATING CARBON CONCENTRATION DISTRIBUTION IN PULSE CARBURIZING PROCESS”, the disclosure of which is incorporated by reference herein in its entirety as part of the present application.

### TECHNICAL FIELD

The present disclosure relates to the field of vacuum low-pressure carburizing, and in particular, to a method for calculating a carbon concentration distribution in a pulse carburizing process.

### BACKGROUND

Vacuum low-pressure carburizing originated from vacuum solid carburizing in the 1960s. In the 1970s, the vacuum solid carburizing had been gradually evolved into carburizing using a low-pressure gas and pulses, and vacuum carburizing dedicated equipment had emerged. In the 1990s, the concept of low-pressure carburizing had been clearly put forward, and it was experimentally demonstrated the advantages of acetylene as a carburizing medium in reducing carbon black production. After 2000, with the progress of research, a vacuum low-pressure carburizing process with acetylene as the carburizing medium and pulses as a working manner had been created. Along with worldwide problems such as environmental degradation and energy crisis, vacuum low-pressure carburizing, as a clean, efficient, and green thermal treatment technique, had received widespread attention.

Obtaining a carbon concentration distribution at a certain time in a carburizing process lays a foundation for describing and controlling a vacuum carburizing process. In atmosphere carburizing, a carbon concentration distribution in a carburizing process can be directly calculated by solving Fick law. Atmosphere carburizing also allows for use of an oxygen probe to measure a carbon potential in real time. Based on the above features, atmosphere carburizing enables real-time display of a carbon concentration variation in the carburizing process. However, this cannot be achieved in a vacuum carburizing process. Due to a vacuum environment, an oxygen probe cannot be used in the vacuum carburizing process and a real-time data feedback cannot be obtained. Meanwhile, vacuum carburizing involves an intensive carburizing-diffusion cyclic pulse process and is complex, and Fick law can only be solved by using a numerical calculation method. According to the numerical calculation method, an equation (e.g., Fick law) may be discretized in space and time by using a finite element method or a finite difference method, and then is solved to obtain a carbon concentration distribution at a certain time in a carburizing process. The accuracy of the numerical calculation method depends on a degree of discretization of the carburized layer in space and time. Therefore, the numerical calculation method often takes a long time for calculation and requires a lot of calculation resources, and cannot calculate a carbon concentration distribution directly and rapidly.

### SUMMARY

In order to solve the above technical problems, the present disclosure provides a method for calculating a gas flow rate in a pulse carburizing process that can provide a gas mass flow rate of a carburizing process, realize high accuracy control of a vacuum low-pressure carburizing process, and increase a carbon utilization ratio of a carburizing gas.

A method for rapidly calculating a carbon concentration distribution in a pulse carburizing process includes the following steps:
calculation of a carburized layer depth: calculating a distance of a position where a carbon concentration first reaches a matrix carbon concentration from a surface to a core part, from the surface when a carburizing stage ends;
segmentation of a carburized layer: segmenting the carburized layer into finite segments within the carburized layer depth;
curve fitting: fitting a carbon concentration distribution using a polynomial within each segment of the carburized layer; and
integral calculation of a carbon concentration: substituting a fitted total carbon concentration distribution into an integral equation of Green's function method to ascertain a carbon concentration distribution curve of next carburizing stage.

On the basis of the above solution, the segmentation of a carburized layer may include averagely setting discontinuity points in an equal division manner.

On the basis of the above solution, the curve fitting may include: within each segment of the carburized layer, using a one-variable quartic polynomial containing n+1 terms, selecting n positions, and performing the curve fitting according to the positions and corresponding carbon concentrations by a Lagrangian interpolation method.

On the basis of the above solution, a piecewise function M(z) describing a carbon concentration distribution of the carburized layer obtained by the curve fitting may be in the following form:

$$M ( z ) = \{ \begin{matrix}{\sum }_{i = 0}^{3} {a}_{1 i} {z}^{i} , 0 \leq z < {L}_{1} \\ {\sum }_{i = 0}^{3} {a}_{2 i} {z}^{i} , {L}_{1} \leq z < {L}_{2} \\ {\sum }_{i = 0}^{3} {a}_{3 i} {z}^{i} , {L}_{2} \leq z < {L}_{3} \\ {\sum }_{i = 0}^{3} {a}_{4 i} {z}^{i} , {L}_{3} \leq z < {L}_{4} \\ {C}_{b} , {L}_{4} \leq z < + ∞\end{matrix}$$

where L₁ to L₄ represent the discontinuity points; C_{b} represents the matrix carbon concentration; aᵢⱼ represents a coefficient of the piecewise function; z represents the carburized layer depth; and M(z) represents the carbon concentration distribution of the carburized layer.

On the basis of the above solution, the integral calculation of a carbon concentration may include calculating a field generated with different carbon potential point sources at any initial carbon concentration.

On the basis of the above solution, the integral calculation of a carbon concentration may include:
if next stage is a boost process, the Green's function is a Green's function corresponding to a third-kind boundary condition; and
if next stage is a diffusion process, the Green's function is a Green's function corresponding to a second-kind boundary condition and having a flow rate of zero.

On the basis of the above solution, the integral calculation of a carbon concentration may specifically include:
substituting the piecewise function describing a carbon concentration distribution of the carburized layer obtained by the curve fitting into the integral equation of Green's function method;
where if next stage is the diffusion process, the integral equation is as follows:

$${C}_{D} ( x , t ) = {\int }_{0}^{+ ∞} {G}_{D} ( x , z , t ) M ( z ) dz$$

$$where$$

$${G}_{D} ( x , z , t ) = \frac{1}{\sqrt{4 D π t}} \{ exp [ - \frac{{( x - z )}^{2}}{4 Dt} ] + exp [ - \frac{{( x + z )}^{2}}{4 Dt} ] \}$$

an integral is solved to obtain a carbon concentration distribution C_{D}(x, t) of next stage;
if next stage is the boost process, the integral equation is as follows:

$${C}_{B} ( x , t ) = {C}_{D} ( x , t ) + {\int }_{0}^{+ ∞} {G}_{F} ( x , z , t ) M ( z ) dz + {C}_{Bd} ( x , t )$$

$$where$$

$${C}_{Bd} ( x , t ) = {C}_{g} \{ erfc ( \frac{x}{2 \sqrt{Dt}} ) - exp [ {( B \sqrt{Dt} )}^{2} + Bx ] erfc ( B \sqrt{Dt} + \frac{x}{2 \sqrt{Dt}} ) \}$$

$${G}_{F} ( x , z , t ) = - B exp [ B ( x + z ) + {( B \sqrt{Dt} )}^{2} ] erfc \{ \frac{x + z}{2 \sqrt{Dt}} + B \sqrt{Dt} \}$$

an integral is solved to obtain a carbon concentration distribution C_{B}(x, t) of next stage;

On the basis of the above solution, the method may further include: with a carbon concentration distribution as an initial state, circularly performing the calculation of a carburized layer depth, the segmentation of a carburized layer, the curve fitting, and the integral calculation of a carbon concentration to obtain carbon concentration distributions of all carburizing processes.

On the basis of the above solution, a gas flow rate required in a carburizing process may be calculated according to the carbon concentration distribution; and
the calculation process may include:
calculating a surface carbon concentration C_{S}=C_{B}(0, t) according to the carbon concentration distribution; and
calculating a gas mass flow rate according to the obtained Cₛ and the following formula:

$$J = \frac{13}{12} ρβ A ( {C}_{g} - {C}_{S} ) ,$$

where J, ρ, A, β, and C_{g} represent the gas mass flow rate, a density of a workpiece, an area of the workpiece, the surface transfer coefficient, and a carbon potential, respectively.

The present disclosure further provides a computer-readable storage medium, storing a computer program, where when executed by a processor, the computer program is caused to implement the method for rapidly calculating a carbon concentration distribution in a pulse carburizing process as described in the above technical solution.

The present disclosure has following beneficial effects:
1. The calculation method does not involve an iterative calculation process, can rapidly calculate a carbon concentration distribution at a certain time in the pulse carburizing process, distinguish between the boost process and the diffusion process based on a boundary condition, describe a vacuum low-pressure carburizing process, and present variations of a surface carbon concentration and a carburized depth in the vacuum low-pressure carburizing process over time.
2. The calculation method has high calculation efficiency, can be embedded in a computer such as an industrial personal computer with ordinary performance for use, may realize real-time display of a carbon concentration in a vacuum carburizing process, and can be used for industrial visual software. By the calculation method in the present disclosure, a vacuum low-pressure carburizing process may be designed. By the method in combination with an iterative calculation method (such as ascertaining a maximum and a minimum using a numerical calculation method), a time to reach a certain surface carbon concentration or a carburized layer depth (a carbon content is 0.35 wt %) is given, whereby a specific process is designed. By comparing carburizing times of different carburizing manners, a carburizing manner with a short process time may be selected, giving full play to efficient and green technical characteristics of vacuum low-pressure carburizing.
3. The method is also applicable to any combination of a finite number of intensive carburizing and diffusion processes, and can be promoted widespread. Meanwhile, the method may use a discrete carbon concentration distribution including a finite number of position-carbon concentration points and has intensive practicability.

### BRIEF DESCRIPTION OF THE DRAWINGS

The present disclosure has the following drawings and tables:

FIG. 1 shows carbon concentration distributions at different times in a fifth carburizing process (a boost process) obtained by a calculation method in the present disclosure in Example 1;

FIG. 2 shows carbon concentration distributions at different times in a sixth carburizing process (a diffusion process) obtained by a calculation method in the present disclosure in Example 1;

FIG. 3 shows a relationship of a surface carbon concentration and a time in a carburizing process in Example 1;

FIG. 4 shows a relationship of a carburized layer depth and a time in a carburizing process in Example 1;

FIG. 5 shows carbon concentration distributions at different times in a first carburizing process (a boost process) obtained by a calculation method in the present disclosure in Example 2; and

FIG. 6 shows carbon concentration distributions at different times in a second carburizing process (a boost process) obtained by a calculation method in the present disclosure in Example 2; and

FIG. 7 is a block diagram showing steps of the present disclosure.

### DETAILED DESCRIPTION OF THE EMBODIMENTS

The present disclosure will be further explained in conjunction with the drawings and tables as well as specific examples. It should be understood that these examples are intended to illustrate the present disclosure rather than limit the scope of the present disclosure. Various equivalent modifications to the present disclosure made by those skilled in the art after reading the specification shall fall within the scope defined by the appended claims.

A method for rapidly calculating a carbon concentration distribution in a pulse carburizing process includes calculation of a carburized layer depth, segmentation of a carburized layer, curve fitting, and integral calculation of a carbon concentration.

The calculation of a carburized layer depth refers to calculating a distance of a position where a carbon concentration first reaches a core part carbon concentration from a surface to a core part, from the surface when a carburizing stage ends.

The segmentation of a carburized layer refers to segmenting the carburized layer into finite segments within the carburized layer depth.

The curve fitting refers to fitting a carbon concentration distribution using a polynomial within each segment of the carburized layer.

The integral calculation of a carbon concentration refers to substituting a fitted total carbon concentration distribution into an integral equation of Green's function method to ascertain a carbon concentration distribution curve of next carburizing stage.

The In order to more clearly show the technical solutions provided by the present disclosure and the technical effects produced, the present disclosure will be described in detail below with specific examples.

### Example 1

A surface transfer coefficient of a workpiece is 4.48×10⁻⁸ m/s; a diffusion coefficient is 1.49×10⁻¹¹ m²/s; a surface area of the workpiece is 1 m²; and a density of the workpiece is 7.8×10³ kg/m³.

A time and a type of each process during a carburizing process are as shown in Table 1.

TABLE 1

| Process No. | Carburizing Process Type | Time, s |
|---|---|---|
| 1 | Boost process | 505 |
| 2 | Diffusion process | 178 |
| 3 | Boost process | 137 |
| 4 | Diffusion process | 243 |
| 5 | Boost process | 121 |
| 6 | Diffusion process | 302 |
| 7 | Boost process | 114 |
| 8 | Diffusion process | 359 |
| 9 | Boost process | 109 |
| 10 | Diffusion process | 415 |
| 11 | Boost process | 107 |
| 12 | Diffusion process | 470 |
| 13 | Boost process | 104 |
| 14 | Diffusion process | 1695 |

A matrix carbon concentration is 0.2 wt. %, and a carburizing gas is acetylene.

A method for calculating a carbon gas flow rate in a pulse carburizing process is carried out according to the following steps.
(1) An initial state is a non-carburized state of a workpiece, i.e., an internal carbon concentration of the workpiece is a matrix carbon concentration; and a carbon concentration distribution of an initial process is identical to that of atmosphere carburizing.
(2) Calculation of a carburized layer depth: using a numerical algorithm, a distance of a position where a carbon concentration first reaches a core part carbon concentration from a surface to a core part, from the surface when a carburizing stage ends is calculated as the carburized layer depth.
(3) Segmentation of a carburized layer: the carburized layer is equally divided into four segments.
(4) Curve fitting: within each segment of the carburized layer, a cubic one-variable quartic polynomial containing 4 terms are used, positions which are 0, 0.3, 0.6, and 1 of a length of each segment are selected, and the curve fitting is performed according to the positions and corresponding carbon concentrations by a Lagrangian interpolation method.
(5) Integral calculation of a carbon concentration distribution: the integral calculation of a carbon concentration refers to calculating a field generated with different carbon potential point sources at any initial carbon concentration.

A piecewise function M(z) describing a carbon concentration distribution of the carburized layer is obtained by the previous fitting process, and M(z) is used to describe an initial carbon concentration distribution and is in the following form:

$$M ( z ) = \{ \begin{matrix}{\sum }_{i = 0}^{3} {a}_{1 i} {z}^{i} , 0 \leq z < {L}_{1} \\ {\sum }_{i = 0}^{3} {a}_{2 i} {z}^{i} , {L}_{1} \leq z < {L}_{2} \\ {\sum }_{i = 0}^{3} {a}_{3 i} {z}^{i} , {L}_{2} \leq z < {L}_{3} \\ {\sum }_{i = 0}^{3} {a}_{4 i} {z}^{i} , {L}_{3} \leq z < {L}_{4} \\ {C}_{b} , {L}_{4} \leq z < + ∞\end{matrix}$$

where L₁ to L₄ represent discontinuity points; C_{b} represents the matrix carbon concentration, and aᵢⱼ represents a coefficient of the piecewise function, obtained by calculation in the previous step. M(z) is substituted into an integral equation of Green's function method.

If next stage is a diffusion process, i.e., a point source is constantly zero, the integral equation of the Green's function method is as follows:

$${C}_{D} ( x , t ) = {\int }_{0}^{+ ∞} {G}_{D} ( x , z , t ) M ( z ) dz$$

$$where$$

$${G}_{D} ( x , z , t ) = \frac{1}{\sqrt{4 D π t}} \{ exp [ - \frac{{( x - z )}^{2}}{4 Dt} ] + exp [ - \frac{{( x + z )}^{2}}{4 Dt} ] \}$$

An integral is solved to obtain a carbon concentration distribution C_{D}(x, t) of next process.

If next carburizing process is a boost process, the boost process has a point source where a carbon potential remains unchanged, and the integral equation of the Green's function method is as follows:

$${C}_{B} ( x , t ) = {C}_{D} ( x , t ) + {\int }_{0}^{+ ∞} {G}_{F} ( x , z , t ) M ( z ) dz + {C}_{Bd} ( x , t )$$

$$where$$

$${C}_{Bd} ( x , t ) = {C}_{g} \{ erfc ( \frac{x}{2 \sqrt{Dt}} ) - exp [ {( B \sqrt{Dt} )}^{2} + Bx ] erfc ( B \sqrt{Dt} + \frac{x}{2 \sqrt{Dt}} ) \}$$

$${G}_{F} ( x , z , t ) = - B exp [ B ( x + z ) + {( B \sqrt{Dt} )}^{2} ] erfc \{ \frac{x + z}{2 \sqrt{Dt}} + B \sqrt{Dt} \}$$

An integral is solved to obtain a carbon concentration distribution C_{B}(x, t) of next process.

If the current carburizing process is a linear carbon potential rising process, i.e., a point source where a carbon potential linearly rises, equations are as follows:

$$G ( x , z , t ) = \frac{1}{\sqrt{4 D π ( t - τ )}} \{ exp [ - \frac{{( x - z )}^{2}}{4 D ( t - τ )} ] + exp [ - \frac{{( x + z )}^{2}}{4 D ( t - τ )} ] \} - B exp [ B ( x + z ) + {( B \sqrt{D ( t - τ )} )}^{2} ] erfc \{ \frac{x + z}{2 \sqrt{D ( t - τ )}} + B \sqrt{D ( t - τ )} \} \qquad ( Formula 1 )$$

$$S ( τ ) = β [ ( {C}_{g} - {C}_{b} ) \frac{τ}{{t}_{0}} + {C}_{b} ] \qquad ( Formula 2 )$$

where D represents a diffusion coefficient (m²/s);
β represents a surface transfer coefficient (m/s);
B: β/D;
C_{g} represents a carbon potential (wt. %);
C_{b} represents the matrix carbon concentration (wt. %); and
t₀ represents a time for the carbon potential to rise from the matrix carbon concentration C_{b} to C_{g}.

An integral is solved so that the carbon concentration distribution C(x, t) of the current carburizing process can be obtained. τ represents a carburizing time for integral calculation; and z represents a carburized layer depth for integral calculation.

In addition, a process in which a surface carbon concentration remains unchanged is further included.
(6) For each carburizing process, the calculation processes of step (2) to step (5) are repeated to obtain carbon concentration distributions of all carburizing processes.

### Result Analysis:

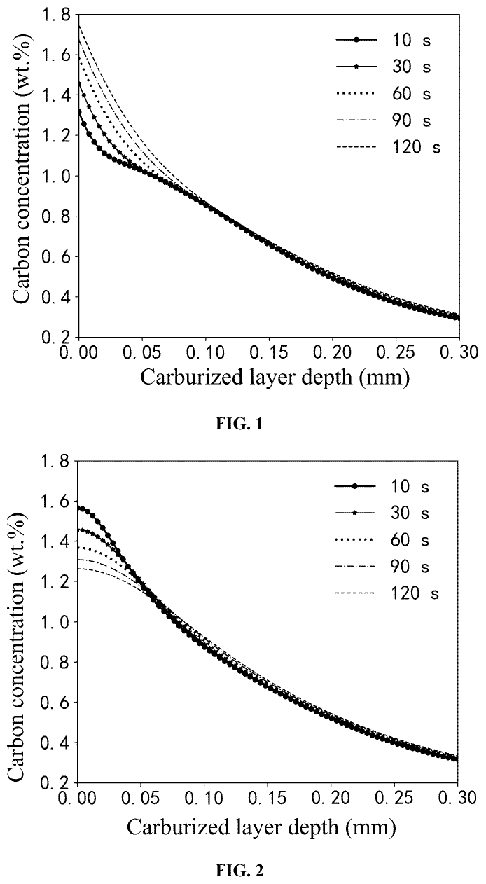

FIG. 1 shows carbon concentration distributions at different times in a fifth carburizing process (the boost process) obtained by the calculation method in the present disclosure. As can be seen from the figure, during the boost process, the carbon concentration within the carburized layer increases constantly with increasing carburizing time. The carbon concentration increases faster when getting closer to the surface.

FIG. 2 shows carbon concentration distributions at different times in a sixth carburizing process (the diffusion process) obtained by the calculation method in the present disclosure. As can be seen from the figure, during the diffusion process, the carbon concentration at a position closer to the surface decreases constantly with increasing carburizing time, while the carbon concentration at a position closer to the core part increases constantly. FIG. 1 and FIG. 2 indicate that the calculation method in the present disclosure can effectively calculate the carbon concentration distribution during the carburizing process. Under the condition of single core calculation at a primary frequency 1.60 GHz, the whole calculation process takes 12 seconds, which is far less than 10-20 minutes for existing finite element software, proving that the calculation method in the present disclosure realizes rapid calculation.

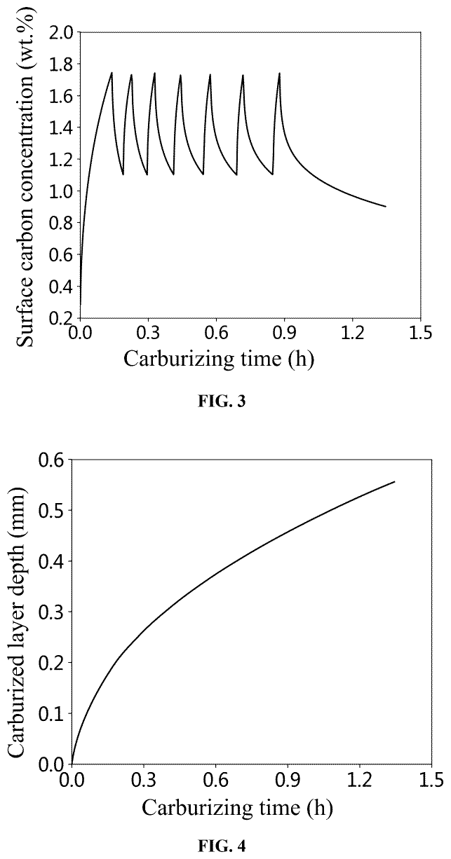

FIG. 3 shows a relationship of a surface carbon concentration and a time in a carburizing process. As can be seen from the figure, the surface carbon concentration increases in the boost process and decreases in the diffusion process. FIG. 4 shows relationship of a carburized layer depth and a time in a carburizing process. As can be seen from the figure, the carburized layer depth increases constantly with creasing time. FIG. 3 and FIG. 4 indicate that the calculation method in the present disclosure can give information such as a surface carbon concentration variation and a carburized layer depth variation in the carburizing process.

### Example 2

A surface transfer coefficient of a workpiece is 3.9×10⁻⁸ m/s; a diffusion coefficient is 1.4×10⁻¹¹ m²/s; a surface area of the workpiece is 1 m²; and a density of the workpiece is 7.8×10³ kg/m³.

TABLE 2

| Process No. | Carburizing Process Type | Time, s |
|---|---|---|
| 1 | Boost process | 100 |
| 2 | Boost process | 133 |
| 3 | Diffusion process | 1629 |
| 4 | Boost process | 222 |
| 5 | Diffusion process | 2414 |
| 6 | Boost process | 219 |
| 7 | Diffusion process | 799 |

A time and a type of each process during a carburizing process are as shown in Table 2, and an initial carbon concentration distribution is as shown in Table 3, with a carburizing gas: acetylene.

TABLE 3

| Position | Carbon concentration |
|---|---|
| 0 | 0.7 |
| 0.042 | 0.682 |
| 0.083 | 0.633 |
| 0.125 | 0.562 |
| 0.167 | 0.482 |
| 0.208 | 0.404 |
| 0.25 | 0.338 |
| 0.292 | 0.287 |
| 0.333 | 0.252 |
| 0.375 | 0.229 |
| 0.417 | 0.215 |
| 0.458 | 0.207 |
| 0.5 | 0.203 |

A method for calculating a carbon concentration distribution in a pulse carburizing process is carried out according to the following steps.
(1) an initial state is a carbon concentration distribution shown in Table 3.
(2) Calculation of a carburized layer depth: using a numerical algorithm, a distance of a position where a carbon concentration first reaches a core part carbon concentration from a surface to a core part, from the surface when a carburizing stage ends is calculated as the carburized layer depth. For a discrete carbon concentration distribution, the last point is directly used as the carburized layer depth. The carburized layer depth of the discrete carbon concentration distribution in this example is 0.5 mm.
(3) Segmentation of a carburized layer: the carburized layer is divided into four segments, which are 0-0.26 (a first segment), 0.26-0.49 (a second segment), 0.49-0.73 (a third segment), and 0.73-1 (a fourth segment) of the carburized layer depth. For the discrete carbon concentration distribution, four segments are divided in such a manner that 4 points are taken as one segment.
(4) Curve fitting: within each segment of the carburized layer, a cubic one-variable quartic polynomial containing 4 terms are used, positions which are 0, 0.35, 0.70, and 1 of a length of each segment are selected, and the curve fitting is performed according to the positions and corresponding carbon concentrations by a Lagrangian interpolation method. For the discrete carbon concentration distribution, 4 points in each segment are directly used as data for curve fitting.
(5) Integral calculation of a carbon concentration distribution: a piecewise function M(z) obtained in the previous process is in the following form:

$$M ( z ) = \{ \begin{matrix}{\sum }_{i = 0}^{3} {a}_{1 i} {z}^{i} , 0 \leq z < {L}_{1} \\ {\sum }_{i = 0}^{3} {a}_{2 i} {z}^{i} , {L}_{1} \leq z < {L}_{2} \\ {\sum }_{i = 0}^{3} {a}_{3 i} {z}^{i} , {L}_{2} \leq z < {L}_{3} \\ {\sum }_{i = 0}^{3} {a}_{4 i} {z}^{i} , {L}_{3} \leq z < {L}_{4} \\ {C}_{b} , {L}_{4} \leq z < + ∞\end{matrix}$$

where L₁ to L₄ represent discontinuity points; C_{b} represents the matrix carbon concentration, and aᵢⱼ represents a coefficient of the piecewise function, obtained by calculation in the previous step. M(z) is substituted into an integral equation of Green's function method. If next stage is a diffusion process, the equation is as follows:

$${C}_{D} ( x , t ) = {\int }_{0}^{+ ∞} {G}_{D} ( x , z , t ) M ( z ) dz$$

$$where$$

$${G}_{D} ( x , z , t ) = \frac{1}{\sqrt{4 D π t}} \{ exp [ - \frac{{( x - z )}^{2}}{4 Dt} ] + exp [ - \frac{{( x + z )}^{2}}{4 Dt} ] \}$$

An integral is solved to obtain a carbon concentration distribution C_{D}(x, t) of next process.

If the current carburizing process is a boost process, the equation is as follows:

$${C}_{B} ( x , t ) = {C}_{D} ( x , t ) + {\int }_{0}^{+ ∞} {G}_{F} ( x , z , t ) M ( z ) dz + {C}_{Bd} ( x , t )$$

$$where$$

$${C}_{Bd} ( x , t ) = {C}_{g} \{ erfc ( \frac{x}{2 \sqrt{Dt}} ) - exp [ {( B \sqrt{Dt} )}^{2} + Bx ] erfc ( B \sqrt{Dt} + \frac{x}{2 \sqrt{Dt}} ) \}$$

$${G}_{F} ( x , z , t ) = - B exp [ B ( x + z ) + {( B \sqrt{Dt} )}^{2} ] erfc \{ \frac{x + z}{2 \sqrt{Dt}} + B \sqrt{Dt} \}$$

An integral is solved to obtain a carbon concentration distribution C_{B}(x, t) of next process.
(6) For each carburizing process, the calculation processes of step (2) to step (5) are repeated to obtain carbon concentration distributions of all carburizing processes.

### Result Analysis:

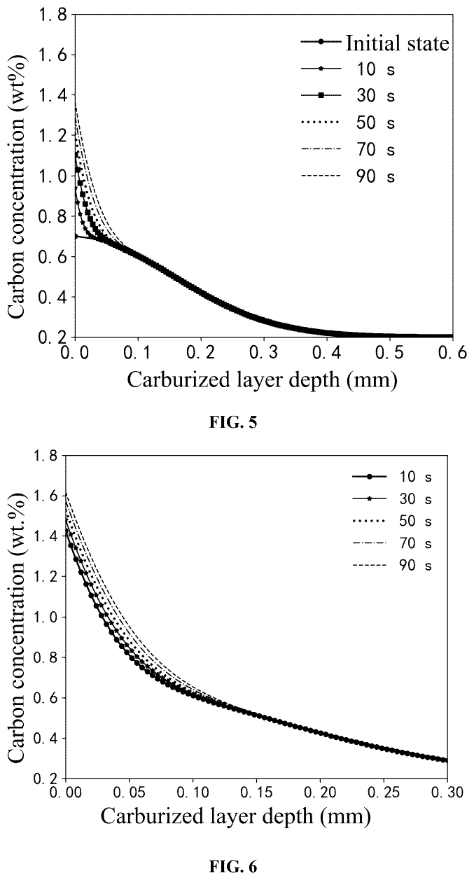

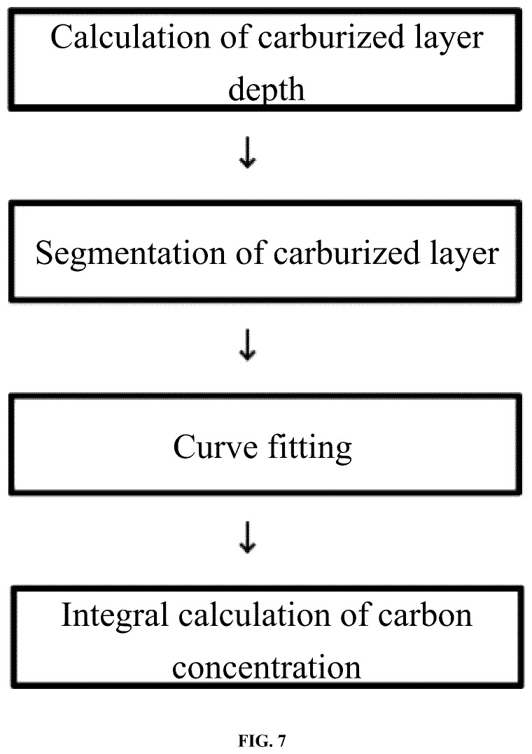

FIG. 5 shows carbon concentration distributions at different times in a first carburizing process (the boost process) obtained by the calculation method in the present disclosure. As can be seen from the figure, during the boost process, the carbon concentration within the carburized layer increases constantly with increasing carburizing time. FIG. 5 indicates the initial condition of the method is not limited to the carbon concentration distribution having an analytic equation, and the method is also applicable to a discrete carbon concentration distribution including a finite number of position-carbon concentration points and has strong practicability.

FIG. 6 shows carbon concentration distributions at different times in a second carburizing process (the boost process) obtained by the calculation method in the present disclosure. FIG. 5 and FIG. 6 indicate that the calculation method of the present disclosure is not limited to intensive carburizing-diffusion pulse cyclic process and is applicable to any combination of a finite number of intensive carburizing and diffusion processes, and can be promoted widespread. Example 2 shows that the method is also applicable when different workpiece parameters and curve fitting manners are adopted. Under the condition of single core calculation at a primary frequency 1.60 GHz, the whole calculation process takes 6 seconds (compared with Example 1, the steps are less), which is far less than 10-20 minutes for existing finite element software, proving that the calculation method in the present disclosure realizes rapid calculation.

The content not described in detail in the description belongs to the prior art well known to those skilled in the art.

What is claimed is:

1. A method for rapidly calculating a carbon concentration distribution in a pulse carburizing process, comprising:
calculation of a carburized layer depth: calculating a distance of a position where a carbon concentration first reaches a matrix carbon concentration from a surface to a core part, from the surface when a carburizing stage ends;
segmentation of a carburized layer: segmenting the carburized layer into finite segments within the carburized layer depth;
curve fitting: fitting a carbon concentration distribution using a polynomial within each segment of the carburized layer; and
integral calculation of a carbon concentration: substituting a fitted total carbon concentration distribution into an integral equation of Green's function method to ascertain a carbon concentration distribution curve of next carburizing stage.

2. The method according to claim 1, wherein the segmentation of a carburized layer comprises averagely setting discontinuity points in an equal division manner.

3. The method according to claim 1, wherein the curve fitting comprises:
within each segment of the carburized layer, using a one-variable quartic polynomial containing n+1 terms, selecting n positions, and performing the curve fitting according to the positions and corresponding carbon concentrations by a Lagrangian interpolation method.

4. The method according to claim 3, wherein a piecewise function M(z) describing a carbon concentration distribution of the carburized layer obtained by the curve fitting is in the following form:
$$M ( z ) = \{ \begin{matrix}{\sum }_{i = 0}^{3} {a}_{1 i} {z}^{i} , 0 \leq z < {L}_{1} \\ {\sum }_{i = 0}^{3} {a}_{2 i} {z}^{i} , {L}_{1} \leq z < {L}_{2} \\ {\sum }_{i = 0}^{3} {a}_{3 i} {z}^{i} , {L}_{2} \leq z < {L}_{3} \\ {\sum }_{i = 0}^{3} {a}_{4 i} {z}^{i} , {L}_{3} \leq z < {L}_{4} \\ {C}_{b} , {L}_{4} \leq z < + ∞\end{matrix}$$
wherein L₁ to L₄ represent the discontinuity points; C_{b} represents the matrix carbon concentration; aᵢⱼ represents a coefficient of the piecewise function; z represents the carburized layer depth; and M(z) represents the carbon concentration distribution of the carburized layer.

5. The method according to claim 1, wherein the integral calculation of a carbon concentration comprises calculating a field generated with different carbon potential point sources at any initial carbon concentration.

6. The method according to claim 5, wherein the integral calculation of a carbon concentration comprises:
if next stage is a boost process, the Green's function is a Green's function corresponding to a third-kind boundary condition; and
if next stage is a diffusion process, the Green's function is a Green's function corresponding to a second-kind boundary condition and having a flow rate of zero.

7. The method according to claim 3, wherein
the integral calculation of a carbon concentration specifically comprises:
substituting the function obtained by the curve fitting or M(z) into the integral equation of Green's function method;
wherein if next stage is the diffusion process, the integral equation is as follows:
$${C}_{D} ( x , t ) = {\int }_{0}^{+ ∞} {G}_{D} ( x , z , t ) M ( z ) dz$$
$$wherein$$
$${G}_{D} ( x , z , t ) = \frac{1}{\sqrt{4 D π t}} \{ exp [ - \frac{{( x - z )}^{2}}{4 Dt} ] + exp [ - \frac{{( x + z )}^{2}}{4 Dt} ] \}$$
an integral is solved to obtain a carbon concentration distribution C_{D}(x, t) of next stage; in the above formula, x represents a carburized layer depth; t represents a carburizing time; z represents the carburized layer depth, which is an intermediate variable of the integral calculation; and D represents a diffusion coefficient; and
if next stage is the boost process, the integral equation is as follows:
$${C}_{B} ( x , t ) = {C}_{D} ( x , t ) + {\int }_{0}^{+ ∞} {G}_{F} ( x , z , t ) M ( z ) dz + {C}_{B d} ( x , t )$$
$$wherein$$
$${C}_{B d} ( x , t ) = {C}_{g} \{ erfc ( \frac{x}{2 \sqrt{D t}} ) - exp [ {( B \sqrt{D t} )}^{2} + Bx ] erfc ( B \sqrt{D t} + \frac{x}{2 \sqrt{D t}} ) \}$$
$${G}_{F} ( x , z , t ) = - B exp [ B ( x + z ) + {( B \sqrt{D t} )}^{2} ] erfc \{ \frac{x + z}{2 \sqrt{D t}} + B \sqrt{D t} \}$$
an integral is solved to obtain a carbon concentration distribution C_{B}(x, t) of next stage; in the above formula, β represents a surface transfer coefficient,
$$B = \frac{β}{D} .$$

8. The method according to claim 1, further comprising: with a carbon concentration distribution as an initial state, circularly performing the calculation of a carburized layer depth, the segmentation of a carburized layer, the curve fitting, and the integral calculation of a carbon concentration to obtain carbon concentration distributions of all carburizing processes.

9. The method according to claim 8, wherein a gas flow rate required in a carburizing process is calculated according to the carbon concentration distribution; and
the calculation process comprises:
calculating a surface carbon concentration C_{S}=C_{B}(0, t) according to the carbon concentration distribution; and
calculating a gas mass flow rate according to the obtained Cₛ and the following formula:
$$J = \frac{13}{12} ρβ A ( {C}_{g} - {C}_{s} ) ,$$
wherein J, ρ, A, β, and C_{g} represent the gas mass flow rate, a density of a workpiece, an area of the workpiece, the surface transfer coefficient, and a carbon potential, respectively.

10. A computer-readable storage medium, storing a computer program, wherein when executed by a processor, the computer program is caused to implement the method for rapidly calculating a carbon concentration distribution in a pulse carburizing process according to claim 1.

11. The method according to claim 4, wherein
the integral calculation of a carbon concentration specifically comprises:
substituting the function obtained by the curve fitting or M(z) into the integral equation of Green's function method;
wherein if next stage is the diffusion process, the integral equation is as follows:
$${C}_{D} ( x , t ) = {\int }_{0}^{+ ∞} {G}_{D} ( x , z , t ) M ( z ) dz$$
$$wherein$$
$${G}_{D} ( x , z , t ) = \frac{1}{\sqrt{4 D π t}} \{ exp [ - \frac{{( x - z )}^{2}}{4 Dt} ] + exp [ - \frac{{( x + z )}^{2}}{4 Dt} ] \}$$
an integral is solved to obtain a carbon concentration distribution C_{D}(x, t) of next stage; in the above formula, x represents a carburized layer depth; t represents a carburizing time; z represents the carburized layer depth, which is an intermediate variable of the integral calculation; and D represents a diffusion coefficient; and
if next stage is the boost process, the integral equation is as follows:
$${C}_{B} ( x , t ) = {C}_{D} ( x , t ) + {\int }_{0}^{+ ∞} {G}_{F} ( x , z , t ) M ( z ) dz + {C}_{B d} ( x , t )$$
$$wherein$$
$${C}_{B d} ( x , t ) = {C}_{g} \{ erfc ( \frac{x}{2 \sqrt{D t}} ) - exp [ {( B \sqrt{D t} )}^{2} + Bx ] erfc ( B \sqrt{D t} + \frac{x}{2 \sqrt{D t}} ) \}$$
$${G}_{F} ( x , z , t ) = - B exp [ B ( x + z ) + {( B \sqrt{D t} )}^{2} ] erfc \{ \frac{x + z}{2 \sqrt{D t}} + B \sqrt{D t} \}$$
an integral is solved to obtain a carbon concentration distribution C_{B}(x, t) of next stage; in the above formula, β represents a surface transfer coefficient,
$$B = \frac{β}{D} .$$

12. The method according to claim 6, wherein
the integral calculation of a carbon concentration specifically comprises:
substituting the function obtained by the curve fitting or M(z) into the integral equation of Green's function method;
wherein if next stage is the diffusion process, the integral equation is as follows:
$${C}_{D} ( x , t ) = {\int }_{0}^{+ ∞} {G}_{D} ( x , z , t ) M ( z ) dz$$
$$wherein$$
$${G}_{D} ( x , z , t ) = \frac{1}{\sqrt{4 D π t}} \{ exp [ - \frac{{( x - z )}^{2}}{4 Dt} ] + exp [ - \frac{{( x + z )}^{2}}{4 Dt} ] \}$$
an integral is solved to obtain a carbon concentration distribution C_{D}(x, t) of next stage; in the above formula, x represents a carburized layer depth; t represents a carburizing time; z represents the carburized layer depth, which is an intermediate variable of the integral calculation; and D represents a diffusion coefficient; and
if next stage is the boost process, the integral equation is as follows:
$${C}_{B} ( x , t ) = {C}_{D} ( x , t ) + {\int }_{0}^{+ ∞} {G}_{F} ( x , z , t ) M ( z ) dz + {C}_{B d} ( x , t )$$
$$wherein$$
$${C}_{B d} ( x , t ) = {C}_{g} \{ erfc ( \frac{x}{2 \sqrt{D t}} ) - exp [ {( B \sqrt{D t} )}^{2} + Bx ] erfc ( B \sqrt{D t} + \frac{x}{2 \sqrt{D t}} ) \}$$
$${G}_{F} ( x , z , t ) = - B exp [ B ( x + z ) + {( B \sqrt{D t} )}^{2} ] erfc \{ \frac{x + z}{2 \sqrt{D t}} + B \sqrt{D t} \}$$
an integral is solved to obtain a carbon concentration distribution C_{B}(x, t) of next stage; in the above formula, β represents a surface transfer coefficient,
$$B = \frac{β}{D} .$$

13. The computer-readable storage medium according to claim 10, wherein the segmentation of a carburized layer comprises averagely setting discontinuity points in an equal division manner.

14. The computer-readable storage medium according to claim 10, wherein the curve fitting comprises: within each segment of the carburized layer, using a one-variable quartic polynomial containing n+1 terms, selecting n positions, and performing the curve fitting according to the positions and corresponding carbon concentrations by a Lagrangian interpolation method.

15. The computer-readable storage medium according to claim 14, wherein a piecewise function M(z) describing a carbon concentration distribution of the carburized layer obtained by the curve fitting is in the following form:
$$M ( z ) = \{ \begin{matrix}{\sum }_{i = 0}^{3} {a}_{1 i} {z}^{i} , 0 \leq z < {L}_{1} \\ {\sum }_{i = 0}^{3} {a}_{2 i} {z}^{i} , {L}_{1} \leq z < {L}_{2} \\ {\sum }_{i = 0}^{3} {a}_{3 i} {z}^{i} , {L}_{2} \leq z < {L}_{3} \\ {\sum }_{i = 0}^{3} {a}_{4 i} {z}^{i} , {L}_{3} \leq z < {L}_{4} \\ {C}_{b} , {L}_{4} \leq z < + ∞\end{matrix}$$
wherein L₁ to L₄ represent the discontinuity points; C_{b} represents the matrix carbon concentration; aᵢⱼ represents a coefficient of the piecewise function; z represents the carburized layer depth; and M(z) represents the carbon concentration distribution of the carburized layer.

16. The computer-readable storage medium according to claim 10, wherein the integral calculation of a carbon concentration comprises calculating a field generated with different carbon potential point sources at any initial carbon concentration.

17. The computer-readable storage medium according to claim 16, wherein the integral calculation of a carbon concentration comprises:
if next stage is a boost process, the Green's function is a Green's function corresponding to a third-kind boundary condition; and
if next stage is a diffusion process, the Green's function is a Green's function corresponding to a second-kind boundary condition and having a flow rate of zero.

18. The computer-readable storage medium according to claim 14, wherein
the integral calculation of a carbon concentration specifically comprises:
substituting the function obtained by the curve fitting or M(z) into the integral equation of Green's function method;
wherein if next stage is the diffusion process, the integral equation is as follows:
$${C}_{D} ( x , t ) = {\int }_{0}^{+ ∞} {G}_{D} ( x , z , t ) M ( z ) dz$$
$$wherein$$
$${G}_{D} ( x , z , t ) = \frac{1}{\sqrt{4 D π t}} \{ exp [ - \frac{{( x - z )}^{2}}{4 Dt} ] + exp [ - \frac{{( x + z )}^{2}}{4 Dt} ] \}$$
an integral is solved to obtain a carbon concentration distribution C_{D}(x, t) of next stage; in the above formula, x represents a carburized layer depth; t represents a carburizing time; z represents the carburized layer depth, which is an intermediate variable of the integral calculation; and D represents a diffusion coefficient; and
if next stage is the boost process, the integral equation is as follows:
$${C}_{B} ( x , t ) = {C}_{D} ( x , t ) + {\int }_{0}^{+ ∞} {G}_{F} ( x , z , t ) M ( z ) dz + {C}_{B d} ( x , t )$$
$$wherein$$
$${C}_{B d} ( x , t ) = {C}_{g} \{ erfc ( \frac{x}{2 \sqrt{D t}} ) - exp [ {( B \sqrt{D t} )}^{2} + Bx ] erfc ( B \sqrt{D t} + \frac{x}{2 \sqrt{D t}} ) \}$$
$${G}_{F} ( x , z , t ) = - B exp [ B ( x + z ) + {( B \sqrt{D t} )}^{2} ] erfc \{ \frac{x + z}{2 \sqrt{D t}} + B \sqrt{D t} \}$$
an integral is solved to obtain a carbon concentration distribution C_{B}(x, t) of next stage; in the above formula, β represents a surface transfer coefficient,
$$B = \frac{β}{D} .$$

19. The computer-readable storage medium according to claim 10, further comprising: with a carbon concentration distribution as an initial state, circularly performing the calculation of a carburized layer depth, the segmentation of a carburized layer, the curve fitting, and the integral calculation of a carbon concentration to obtain carbon concentration distributions of all carburizing processes.

20. The computer-readable storage medium according to claim 19, wherein a gas flow rate required in a carburizing process is calculated according to the carbon concentration distribution; and
the calculation process comprises:
calculating a surface carbon concentration C_{S}=C_{B}(0, t) according to the carbon concentration distribution; and
calculating a gas mass flow rate according to the obtained Cₛ and the following formula:
$$J = \frac{13}{12} ρβ A ( {C}_{g} - {C}_{s} ) ,$$
wherein J, ρ, A, β, and C_{g} represent the gas mass flow rate, a density of a workpiece, an area of the workpiece, the surface transfer coefficient, and a carbon potential, respectively.
